(19) United States
(12) Patent Application Publication
(10) Pub. No.: US 2004/0053454 A1
(43) Pub. Date: Mar. 18, 2004

(54) Method of forming lightly doped drains

(76) Inventor: Kun-Hong Chen, Taipei (TW)

Correspondence Address: Michael D. Bednarek, Shaw Pittman LLP, 1650 Tysons Boulevard, McLean, VA, 22102, US

(21) Appl. No.: 10/627,751

(22) Filed: Jul. 28, 2003

(30) Foreign Application Priority Data
Sep. 12, 2002 (TW) 091120870

(51) Int. Cl. H01L 21/00; H01L 21/84

(52) U.S. Cl. 438/163

(57) ABSTRACT

The present invention provides a method of forming lightly doped drains. The method consists of providing a semiconductor structure and an insulating layer formed on the semiconductor structure. A conductive layer is formed on the insulating layer and a photo resist layer, having a transferred pattern, is formed on the conductive layer. Next, by using the photo resist layer as a first mask, a portion of the conductive layer is removed to expose a portion of the insulating layer. By using the photo resist layer together with the conductive layer as a second mask, multiple first ions are implanted into the semiconductor structure. A portion of the conductive layer is isotropic etched to result in undercut of the conductive layer under the photo resist layer. After the photo resist layer is removed, multiple second ions are implanted into the semiconductor structure to form the lightly doped drains by using the undercut conductive layer as a third mask.

### CROSS REFERENCE TO RELATED APPLICATIONS

This application claims priority of Taiwan Patent Application Serial No. 091120870 filed on Sep. 12, 2002.

### FIELD OF INVENTION

The present invention relates to a method of forming lightly doped drains and, more particularly, to a method of forming lightly doped drains in thin film transistors.

### BACKGROUND OF THE INVENTION

Persons skilled in the art of Liquid Crystal Display (LCD) know that strong electric field near the drain of thin film transistor often leads to high leakage current. Offset gate structure, lightly doped drain structure, or multi-gate structure thus are provided to suppress the electric field. To reduce image quality deterioration caused by the parasitic capacitance in offset gate structure and lightly doped drain structure, several steps must be performed to ensure self-alignment of these areas.

In many technical reports, it is disclosed that applying the lightly doped regions may reduce on-state leakage current of the thin film transistors. However, the additional lightly doped regions usually need more masks during fabrication of the thin film transistors, thus leading to higher complexity and cost. Besides, if there exists misalignment of the mask used for ion implantation of the lightly doped drains, length of the lightly doped drains at either sides of the thin film transistor channel may be different.

Therefore continually improving the accuracy of photolithographic alignment and reducing the number of masks during TFT-LCD fabrication are critical issues.

### SUMMARY OF THE INVENTION

One aspect of the present invention provides a method of forming lightly doped drains. The method may avoid the length difference of lightly doped drains caused by misalignment of mask during photolithography process.

Another aspect of the present invention provides a method of forming lightly doped drains in the thin film transistors. The method may avoid the misalignment of mask by using the self-aligning mask, and the self-aligning mask results from undercut of the gate.

The present invention provides a method of forming a lightly doped drain, including providing a semiconductor structure and forming an insulating layer on the semiconductor structure. Then a conductive layer is formed on the insulating layer, and a photo resist layer, having a transferred pattern, is formed on the conductive layer. Next, by using the photo resist layer as a first mask, a portion of the conductive layer is removed to expose a portion of the insulating layer. By using the photo resist layer together with the conductive layer as a second mask, multiple (M) first ions are implanted into the semiconductor structure. A portion of the conductive layer is isotropic etched such that undercut of the conductive layer under the photo resist layer is observed. After removing the photo resist layer, multiple (M) second ions are implanted into the semiconductor structure to form the lightly doped drain. The step of implanting uses the undercut conductive layer as a third mask.

### BRIEF DESCRIPTION OF THE DRAWINGS

FIGS. 1(A) to (F) illustrate cross-section diagrams of the lightly doped drain of thin film transistors fabricated by the method according to the present invention.

### DETAILED DESCRIPTION

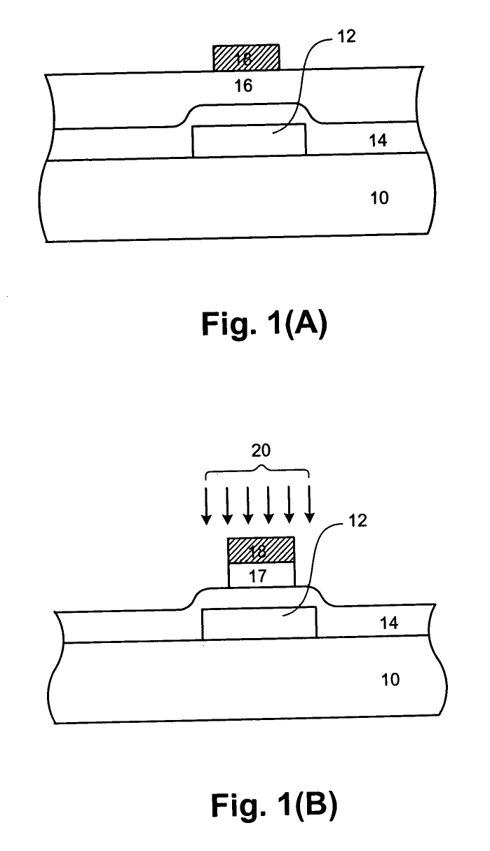

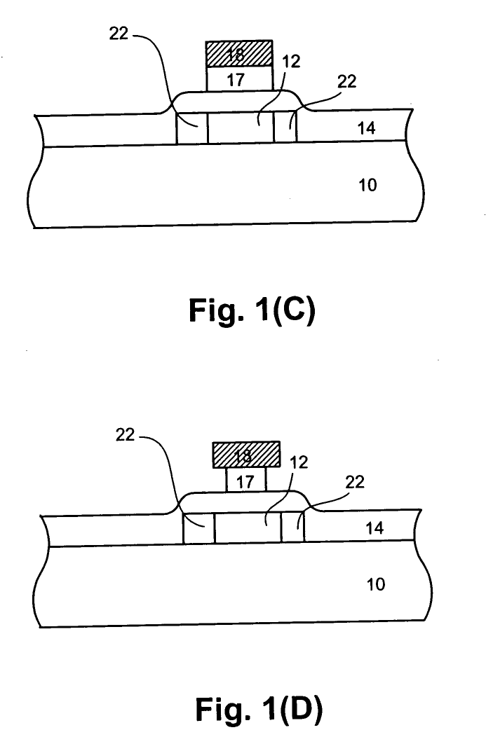

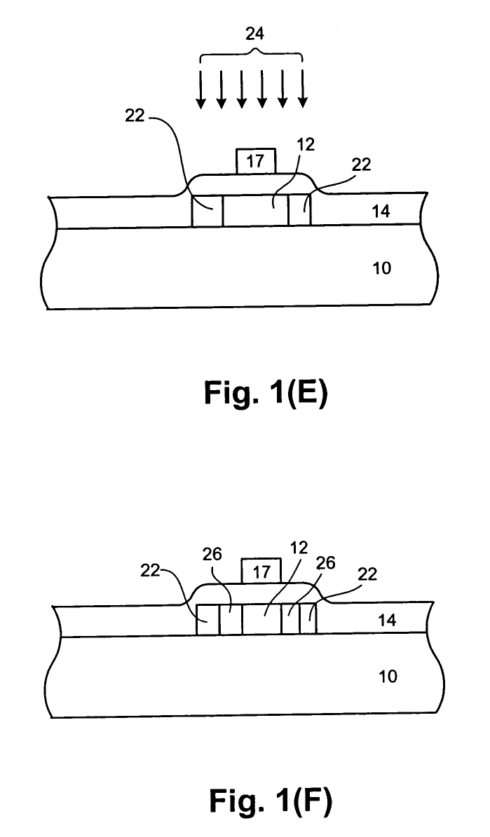

FIGS. 1(A) to (F) illustrate cross-section diagrams of the lightly doped drain of thin film transistors fabricated by the method according to the present invention. Referring to FIG. 1(A), a silicon layer (not shown) is formed on a substrate 10, such as a glass substrate. The silicon layer may be a polysilicon layer, such as one formed by annealing an amorphous layer. A polysilicon structure 12, formed by transferring pattern onto the silicon layer, acts as the active area. An insulating layer 14, such as an oxide layer, a silicon nitride layer, or both, is formed or deposited on the polysilicon layer 12 and the substrate 10. Then a conductive layer 16 is formed on the insulating layer 14. The conductive layer 16 may be a metal layer or an alloy, such as Al/Cr. Then a photo resist layer 18, having a transferred pattern, is formed on the conductive layer 16.

Referring to FIG. 1(B), the conductive layer 16 is defined using the photo resist layer 18, having a transferred pattern, as mask. A portion of conductive layer 16 is removed to expose a portion of insulating layer 14, and the step of removing may be performed by dry etching. And a gate structure 17 is formed on the polysilicon structure 12 from the conductive layer 16. The gate structure 17 is narrower than the polysilicon structure 12. Thus, the polysilicon structure 12 is implanted with ions 20 using the photo resist layer 18 together with the gate structure 17 as an implanting mask.

As shown in FIG. 1(C), since the gate structure 17 is narrower than the polysilicon structure 12, the doped region 22 is formed at both sides of the polysilicon structure 12 by the ions 20. Typically the doped region 22 is used as source and drain of the gate structure 17.

Then as one embodiment of the present invention, referring to FIG. 1(D), the gate structure 17 is isotropically etched by wet etching such that undercut of the gate structure 17 is observed under the photo resist layer 18. Tuning the conditions of wet etching process may lead to near identical undercut extent at both sides of the gate structure 17. It is favorable for the following ion implantation.

As shown in FIG. 1(E), first the photo resist layer 18 is removed, and the ions 24 are implanted into the polysilicon structure 12 using the undercut gate structure 17 as an implanting mask. The undercut gate structure 17 exposes a portion of polysilicon structure 17 between the doped region 22, thus the ions 24 are implanted to form the doped region, as shown in FIG. 1(F). The doped region 26 formed in the doped region 22 is used as the lightly doped drain region of the gate structure 17. Here the undercut gate structure 17 provides better implanting mask definition. The formed doped region 26 is not limited by conventional photolithography alignment and is not easily offset, since the doped region 26 is formed using the undercut gate structure 17 as an implanting mask.

As previously recited, the present invention provides a method of forming a lightly doped drain in a thin film transistor in a CMOS. The method includes providing a glass substrate and a polysilicon structure on the glass substrate. An insulating layer is deposited on the polysilicon structure and the glass substrate. Then a metal layer is deposited on the insulating layer, and a photo resist layer, having a transferred pattern, is formed on the metal layer. A portion of metal layer is dry etched using the photo resist layer as a first mask, and a potion of insulating layer is exposed. Next, multiple ions are implanted into the polysilicon structure using the photo resist layer together with the metal layer as a second mask. A portion of metal layer is isotropically etched such that undercut of the metal layer is observed under the photo resist layer. The photo resist layer is removed, and the ions are implanted into the polysilicon structure to form the lightly doped drains. The step of implanting uses the isotropically etched metal layer as a third mask.

The detailed description of the preferred exemplary embodiment above is intended to describe the features and spirit of the present invention more clearly, but not intended to limit the scope of the present invention. The scope of the claims of the present invention should be most broadly construed according to the above description, to cover all possibly equivalent changes and equivalent arrangements.

1. A method of forming a lightly doped drain comprising:
providing a semiconductor structure;
forming an insulating layer on said semiconductor structure;
forming a conductive layer on said insulating layer;
forming a photo resist layer, having a transferred pattern, on said conductive layer;
removing a portion of said conductive layer to expose a portion of said insulating layer, said step of removing uses said photo resist layer as a first mask;
implanting multiple (M) first ions into said semiconductor structure, said step of implanting uses said photo resist layer and said conductive layer as a second mask;
isotropic etching a portion of said conductive layer such that undercut of said conductive layer under said photo resist layer is observed;
removing said photo resist layer; and
implanting multiple (M) second ions into said semiconductor structure to form said lightly doped drain, said step of implanting uses said undercut conductive layer as a third mask.

2. A method according to claim 1, wherein the semiconductor structure including a substrate and a polysilicon structure on said substrate.

3. A method according to claim 2, wherein the step of implanting said M first ions comprises implanting said M first ions into said polysilicon structure.

4. A method according to claim 2, wherein the step of implanting said M second ions comprises implanting said M second ions into said polysilicon structure.

5. A method according to claim 1, wherein the said conductive layer including a metal layer.

6. A method according to claim 1, wherein the step of removing a portion of said conductive layer comprises dry etching a portion of said conductive layer.

7. A method according to claim 1, wherein the step of forming said insulating layer comprises forming an oxide layer and a silicon nitride layer on said oxide layer.

8. A method of forming a lightly doped drain, said lightly doped drain is formed in a thin film transistor, comprising:
providing a glass substrate and a polysilicon structure on said glass substrate;
depositing an insulating layer on said polysilicon structure and said glass substrate;
depositing a metal layer on said insulating layer;
forming a photo resist layer, having a transferred, pattern on said metal layer;
dry etching a portion of said metal layer to expose a portion of said insulating layer, said step of dry etching uses said photo resist layer as a first mask;
implanting multiple (M) first ions into said polysilicon structure, said step of implanting uses said photo resist layer and said metal layer as a second mask;
isotropic etching a portion of said metal layer such that undercut of said metal layer under said photo resist layer is observed;
removing said photo resist layer; and
implanting multiple (M) second ions into said polysilicon structure to form said lightly doped drain, said step of implanting uses said undercut metal layer as a third mask.

9. A method according to claim 8, wherein the step of isotropic etching comprises wet etching a portion of said metal layer.

10. A method of forming a lightly doped drain comprising:
providing a semiconductor structure, said semiconductor structure including a substrate and a polysilicon structure on said substrate;
forming an insulating layer on said semiconductor structure;
forming a conductive layer on said insulating layer;
forming a photo resist layer, having a transferred, pattern on said conductive layer;
removing a portion of said conductive layer to expose a portion of said insulating layer, said step of removing uses said photo resist layer as a first mask;
implanting multiple (M) first ions into said polysilicon structure, said step of implanting uses said photo resist layer and said conductive layer as a second mask;
isotropic etching a portion of said conductive layer such that undercut of said conductive layer under said photo resist layer is observed;
removing said photo resist layer; and
implanting multiple (M) second ions into said polysilicon structure to form said lightly doped drain, said step of implanting uses said undercut conductive layer as a third mask.

11. A method of forming a lightly doped drain, said lightly doped drain is formed in a thin film transistor, comprising:
providing a glass substrate and a polysilicon structure on said glass substrate;
depositing an insulating layer on said polysilicon structure and said glass substrate;
depositing a metal layer on said insulating layer;
forming a photo resist layer, having a transferred, pattern on said metal layer;
dry etching a portion of said metal layer to expose a portion of said insulating layer, said step of dry etching uses said photo resist layer as a first mask;
implanting multiple (M) first ions into said polysilicon structure, said step of implanting uses said photo resist layer and said metal layer as a second mask;
isotropic etching a portion of said metal layer such that undercut of said metal layer under said photo resist layer is observed, said step of isotropic etching including a step of wet etching;
removing said photo resist layer; and
implanting multiple (M) second ions into said polysilicon structure to form said lightly doped drain, said step of implanting uses said undercut metal layer as a third mask.
